(19) United States
(12) Patent Application Publication
(10) Pub. No.: US 2012/0292484 A1
(43) Pub. Date: Nov. 22, 2012

(54) IMAGE SENSOR

(75) Inventor: Michael Cieslinski, Ottobrunn (DE)

(73) Assignee: Arnold & Richter Cine Technik GmbH & Co. Betriebs KG, Munich (DE)

(21) Appl. No.: 13/471,556

(22) Filed: May 15, 2012

(30) Foreign Application Priority Data
May 16, 2011 (DE) DE 102011101835.6

(51) Int. Cl. H01L 27/148

(52) U.S. Cl. 250/208.1

(57) ABSTRACT

An image sensor for electronic cameras includes a plurality of light-sensitive pixels arranged in rows and columns for generating exposure-dependent pixel signals in an image field. Each pixel includes at least one light-sensitive element to generate electric charge from incident light and a converter transistor to convert a charge into a voltage signal. The pixels form a plurality of pixel groups with at least one common read-out circuit being associated with each pixel group are coupled to the output of the associated converter transistor. An amplifier circuit amplifies the voltage signals from each converter transistor.

### CROSS-REFERENCE TO RELATED APPLICATIONS

This application claims priority of German Patent Application 10 2011 101 835.6 filed May 16, 2011.

### FIELD OF THE INVENTION

The present invention relates to an image sensor, in particular to a CMOS image sensor, for electronic cameras, having a plurality of light-sensitive pixels for generating exposure-dependent pixel signals. The pixels are arranged in rows and columns of an image field, with each pixel including at least one light-sensitive element to generate electric charge from light incident along a direction of exposure and a converter transistor to convert a charge generated by the light-sensitive element into a voltage signal at an output of the converter transistor. The pixels form a plurality of pixel groups, with a plurality of pixels being associated with each pixel group, and with at least one common read-out circuit being associated with the plurality of pixels of each pixel group, said common read-out circuit being able to be coupled to the output of the respective converter transistor of the pixels of the pixel group and including an amplifier circuit for generating amplified voltage signals from the voltage signals.

### BACKGROUND OF THE INVENTION

An electronic camera is used, for example, to digitally record image sequences which are later shown in a cinema. In this respect, it is desirable that the camera also has a high image quality in addition to a high resolution and a high frame rate. It is endeavored for the achieving of the desired image quality to minimize the noise portion in the pixel signals and largely to avoid possible pixel defects which are based, for example, on non-linearities in the generation of the pixel signals. A deficient image quality is in particular easy to recognize for the viewer on the projection onto large screens.

The image sensor of an electronic camera converts light incident through the objective of the camera into electrical signals and comprises a plurality of light-sensitive elements, the so-called pixels, which are usually arranged in rows and columns and form the image field. Image sensors manufactured on a silicon base in CMOS technology are typically used.

To read out an image taken by the camera, the pixels are addressed row-wise, for example, and a voltage proportional to the charge of the respective pixel is generated which is conducted to an output of the image sensor. The pixels arranged in a respective column are associated with at least one common column line and can be selectively connected thereto. The column lines form the so-called column bus and conduct the signals of the pixels to a signal processing circuit arranged at the margin of the image field.

The reading out of such image sensors can take place in different operating modes. On the one hand, the so-called rolling shutter mode is known in which the individual rows of the image sensor are exposed sequentially after one another and each row is read out before the end of the exposure. The control of the exposure takes place in a known manner in that, at the start of the exposure, the charge collected in the pixels to be exposed is deleted by connecting the pixel to a reset potential and the charge generated in the light-sensitive element is accumulated during the predefined exposure time. After the end of the exposure time, the charge accumulated in the light-sensitive element is transferred to the converter transistor and is converted by it into a corresponding voltage signal which is transferred via the column line to the signal processing circuit and is amplified and processed there. The processing of the voltage signal can in particular include the forming of a difference from a reference signal generated by the respective pixel without exposure, which is called correlated double sampling (CDS) and is explained in detail, for example in DE 10 2007 045 448 A1. Furthermore, a conversion of the voltage signals into digital signals can take place in the signal processing circuit.

In the rolling shutter mode, the individual rows of the image field are accordingly exposed with a time offset, with the time required for the reading out of a pixel or of a row of pixels defining the time offset which occurs between the individual rows of the image field. For example, with an image sensor having 1080 rows and a frame rate of 30 frames a second, the time required for the reading out of a row can be approximately 30 μs. A time offset of approximately 33 ms thus arises between the reading out of the first row and of the last row of the image field. This time offset has the result in the taking of moving objects of a distortion of the moving object, which is perceived as distortion by the observer. Rotating rotor blades of a helicopter which are straight per se thus appear as curved in the playback of the image sequence.

To avoid such distortion artifacts, image sensors are used which are operated in the so-called global shutter mode. In the global shutter mode, all the pixels of the image sensor are exposed at the same time. At the end of the exposure time, the charge accumulated in each pixel is transferred to a storage capacitor associated with the respective pixel and is buffered there or is converted into a proportional voltage which is then buffered. The buffered signals are subsequently read out sequentially row by row.

Image sensors for the global shutter mode, however, have a more complex structure since the required storage capacitors take up additional space in the respective pixel. This ultimately results in a reduction of the area of the respective light-sensitive element so that the sensitivity and dynamics of the image sensor is reduced with a simultaneous increase in the noise.

### SUMMARY OF THE INVENTION

It is therefore the object of the invention to provide an image sensor with improved image quality.

The object is satisfied by an image sensor having the features of claim 1 and in particular in that the amplifier circuit of the respective pixel group is arranged within the image field viewed in projection along the direction of exposure of the pixels.

In the image sensor in accordance with the invention, a common amplifier circuit is thus provided for each pixel group in addition to the plurality of converter transistors which effect a charge-to-voltage conversion for each pixel, said common amplifier circuit effecting a voltage gain at the output of the converter transistors of the plurality of pixels for the respective voltage signal. This common amplifier circuit (or group amplifier) is—unlike a conventional column amplifier, for example—arranged within the image field, in particular beneath the plurality of pixels arranged in rows and columns, with respect to a projection along the direction of exposure of the pixels.

The conductor paths are shortened with respect to an image sensor in which the amplifier circuit is provided outside the image field by the arrangement of the amplifier circuit within the image field. The risk that interference signals are superimposed on the voltage signal generated at the output of the respective converter transistors during the transmission to the amplifier circuit and thus result in a deterioration of the signal quality is thereby reduced. Since the amplifier circuit forms a part of the common read-out circuit, more space is available for the amplifier circuit of a respective pixel group than if a separate amplifier circuit is provided for each pixel. The amplifier circuits of the image sensor in accordance with the invention can thus have a relatively complex design and a correspondingly higher quality.

At the same time—depending on the size of the pixel groups—more amplifier circuits can be provided than the maximum number of column amplifiers of a conventional CMOS image sensor. With a conventional image sensor, the column amplifiers are arranged at the margin of the sensor outside the image field. The number of column amplifiers typically corresponds to the number of columns of pixels and amounts to a maximum of twice or four times the column number (with split columns and two column lines per column). In the image sensor in accordance with the invention, this limitation is not present, but the number of the named column amplifiers can rather be selected as higher. The read-out rate can hereby be increased since the read-out rate of an image sensor is not only limited by the respective engagement time of the column lines, but also by the settling times of the amplifiers. The time offset accumulated on the reading out of a complete image can above all hereby be reduced so much that it is considerably below the exposure time and the aforesaid distortion artifacts of a rolling shutter can be avoided.

In accordance with a preferred embodiment of the invention, the respective amplifier circuit furthermore has at least one memory device for buffering the amplified voltage signals for each pixel of the associated pixel group. In this respect, the pixels of a pixel group are addressed after one another to read out the voltage signals, to amplify them and to buffer them in the respective memory device. This can take place at a relatively high speed so that only a very small time offset arises on the reading out of the pixels within a pixel group and distortion artifacts are reduced similarly effectively as with an image sensor which is operated in the global shutter mode. In comparison with such a global shutter image sensor, the signal noise is, however, substantially reduced. Since namely only limited space is available in each pixel and some of this space is already required for the memory device with a conventional global shutter image sensor, an amplifier provided in the pixel for amplifying the voltage signals output at the output of the converter transistor is dispensed with there and the voltage signals are buffered without gain. In contrast to this, an amplification connected before the buffer memory is provided in the image sensor in accordance with the invention.

The respective read-out circuit furthermore includes at least one evaluation circuit which is adapted to evaluate the amplified voltage signals. The transmission of the amplified voltage signals from the amplifier circuit or from the memory devices to the evaluation circuit and the evaluation of the amplified voltage signals can take place at a relatively low speed, in particular slower by a multiple than the exposure and read-out processes.

The division of the read-out circuit into an amplifier circuit which pre-amplifies and buffers the voltage signals of the pixels and an evaluation circuit which accepts the amplified and buffered voltage signals in order subsequently to carry out the remaining signal processing steps makes it possible to separate the reading out of the pixels, including the pre-amplification, and the further signal processing from one another in time and in space. The total read-out process can thereby be accelerated, i.e. the time offset between the exposure processes of the pixels of a pixel group can be reduced so much that the distortion artifacts caused by the sequential exposure are no longer perceivable for a viewer. Since a plurality of pixels share one amplifier circuit, it can include a high-quality and thus space-consuming amplifier without the area available for the light-sensitive elements having to be reduced to an unacceptable degree.

The evaluation circuit is preferably arranged outside the image field since sufficient space is available there.

The evaluation taking place in the evaluation circuit can in particular include a further amplification of the amplified voltage signals so that three hierarchy planes of the signal conversion and signal amplification result: The charge-to-voltage conversion by the converter transistor of the respective pixel, the voltage gain by the amplification circuit of the respective pixel group within the image field and the subsequent voltage gain by a voltage amplifier outside the image field.

Furthermore, the evaluation taking place in the evaluation circuit can include a sampling and/or analog/digital conversion of the amplified voltage signals, but also a signal processing within the framework of the initially explained correlated double sampling.

In accordance with a further preferred embodiment, the respective amplifier circuit has, as already mentioned, at least one memory device for each pixel of the associated pixel group for buffering the amplified voltage signals, with the respective read-out circuit furthermore including a selection circuit to couple the memory devices of the associated pixel group sequentially with the associated evaluation circuit and hereby to output the buffered amplified voltage signals sequentially to the associated evaluation circuit. The selection circuit can optionally be provided in the amplifier circuit or in the evaluation circuit.

It is furthermore also possible to provide first and second memory devices for each pixel which are adapted to carry out the correlated double sampling for a storage of a reference signal and of the actual image signal.

It is furthermore preferred that the image sensor has a number of a plurality of evaluation circuits corresponding to the number of pixel groups with a respective amplifier circuit, a respective evaluation circuit and a respective selection circuit, with the image sensor having a control device which is adapted to control at least some of the plurality of read-out circuits simultaneously. The sequential output of the respective buffered amplified voltage signals to the associated evaluation circuit thus takes place simultaneously for different pixel groups.

In accordance with a further advantageous embodiment, the pixels are arranged on a common first semiconductor substrate and the amplifier circuits are arranged on a common second semiconductor substrate connected to the first substrate. Since a separate semiconductor substrate is provided for the amplifier circuits and since moreover only one common amplifier circuit is provided for a plurality of pixels, the space present on the first semiconductor substrate is essentially available for the pixels and in particular for the light-sensitive elements, whereas the additional space present on the second semiconductor substrate makes it possible to design the amplifier circuits with a particularly high quality and thus with low noise.

The second semiconductor substrate is preferably arranged along the direction of exposure of the pixels beneath the first substrate. Maximum space is thereby available for the light-sensitive elements of the pixels on the first semiconductor substrate so that the image sensor has an ideal quality with respect to a high sensitivity, high signal dynamics and low noise.

The first semiconductor substrate is preferably back-side illuminated. In the manufacture of a back-side illuminated semiconductor substrate, the design takes place such that the light-sensitive elements are located directly on the rear of the substrate (i.e. back-side), whereas the remaining elements such as transistors and connection lines are arranged above. The light-sensitive elements are subsequently exposed by etching or thin grinding. The back-side illuminated semi-conductor substrate is arranged in the image sensor so that the rear side is located at the very top of the image sensor viewed in the direction of exposure of the pixels. A particularly high sensitivity for the incident light thereby results.

Pixels of a different pixel group are preferably arranged between the pixels of a respective pixel group. Pixels of different pixel groups are thereby so-to-say interlaced spatially with one another, which reduces the perceptibility of artifacts due to the initially explained time offset between the individual exposures, in particular in comparison with image sensors in which the individual pixel groups are formed in a conventional manner by those pixels which are connected to a common column line and are arranged in a single column. In this respect, pixels of a different pixel group are preferably arranged between the pixels of the respective pixel group both along a row direction and along a column direction, whereby a particularly effective spatial interlacing is achieved. The named row direction and column direction relate to the respective direction of extent of the rows and columns of the image field. The named row direction and column direction typically extend orthogonally to one another and orthogonally to the named direction of exposure.

It is preferred that each pixel group has an extent of at least two pixels in the column direction and an extent of at least two pixels in the row direction. Distortion artifacts are thereby particularly effectively eliminated.

The pixels of each pixel group are preferably arranged in a pattern which is the same or substantially the same for all the pixel groups of the image sensor. A particularly efficient distribution of the pixels of a pixel group over the image field hereby results. “Substantially the same” is understood such that patterns differing from a plurality of identical patterns are mainly caused by the fact that for geometrical reasons different structures are required for patterns located at the image margin.

In accordance with a further preferred embodiment of the invention, each pixel furthermore includes a read-out node, a transfer transistor (a so-called transistor gate) in order selectively to couple the light-sensitive element to the read-out node and a reset transistor in order selectively to couple the read-out node to a reset potential. The pixels can in particular have a so-called four-transistor arrangement such as is described in DE 10 2007 045 448 A1.

Further advantageous embodiments of the invention are set forth in the dependent claims, in the description and in the drawings.

### BRIEF DESCRIPTION OF THE DRAWINGS

The invention will be explained in the following with reference to an embodiment and to the drawings. There are shown:

FIG. 1 a four-transistor CMOS image sensor in accordance with the prior art, with only one pixel and one column amplifier circuit associated with the column line of the pixel being shown;

FIG. 2 a schematic cross-sectional view of details of a CMOS image sensor in accordance with the present invention;

FIG. 3 a schematic representation of a read-out circuit of a CMOS image sensor in accordance with the present invention; and

FIG. 4 a schematic plan view of details of two planes of a CMOS image sensor in accordance with the present invention.

### DETAILED DESCRIPTION OF THE PREFERRED EMBODIMENTS

The basic mode of operation of an exemplary conventional four-transistor image sensor of the APS type (active pixel sensor) such as is used in the embodiment described in the following is described in detail in DE 10 2007 045 448 A1. The present invention is, however, not generally restricted to active four-transistor image sensors, but can rather also be used in image sensors having fewer or more than four transistors per pixel.

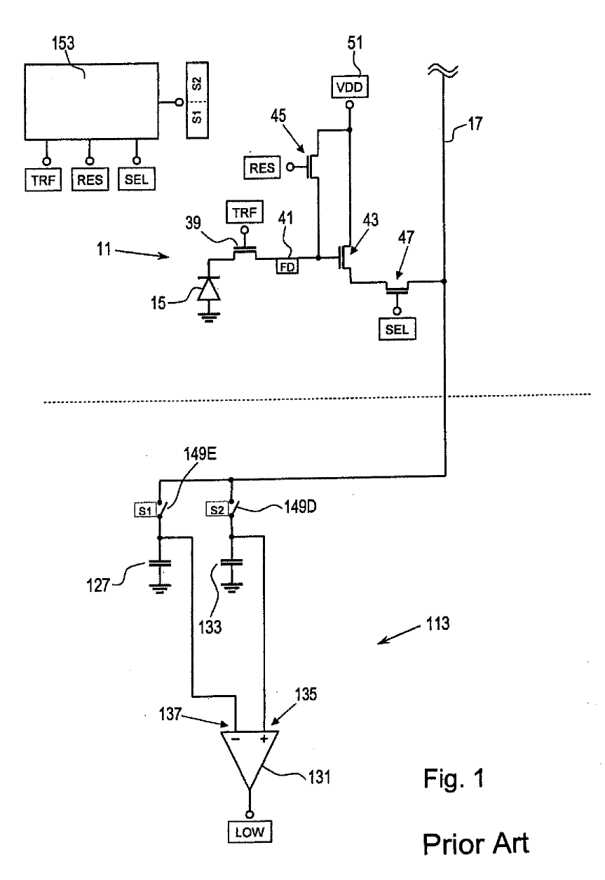

For the better understanding of the invention, such a four-transistor CMOS image sensor will be explained with reference to FIG. 1, with individual components of this image sensor also being present in an image sensor in accordance with the invention.

Only a single pixel 11 is shown as representative in FIG. 1 which includes a light-sensitive detector element in the form of a photodiode, in particular in the form of a so-called pinned diode 15, which is charge-coupled via a switching device in the form of a transfer transistor 39 to a read-out node 41 which is in particular formed as a so-called floating diffusion (FD).

The read-out node 41 is connected to the gate of a converter transistor 43 which is formed as a source follower and which represents a charge-to-voltage converter circuit. Furthermore, the read-out node 41 is connected to a positive voltage supply 51 via a further switching device in the form of a reset transistor 45. One of the two channel connections of the converter transistor 43 is likewise connected to the positive voltage supply 51, whereas the other of the two channel connections of the converter transistor is connectable via a selection transistor 47 which acts as a row selection switch to a column line 17 associated with the pixel shown.

The column line 17 is provided to connect the pixels arranged in an associated column, in particular pixels 11, to a common column read-out circuit, for example to a column amplifier circuit 113. The column amplifier circuit 113 includes a first capacitor or reference value capacitor 127 which is connected to ground by a connection and is selectively connectable to the other connection via a switch 149E to the column line 17. The column amplifier circuit 113 furthermore includes a second capacitor or signal value capacitor 133 which is likewise connected to ground by a connection and is connectable by the other connection via a further switch 149D likewise selectively to the column line 17.

The column amplifier circuit 113 furthermore includes an amplifier 131 at whose negative input 137 the voltage applied to the first capacitor 127 is applied and at whose positive input 135 the voltage applied to the second capacitor 133 is applied.

The transfer transistor 139 is controllable via a control line TRF; the reset transistor 45 is controllable via a control line RES; the selection transistor 47 is controllable via a control line SEL; the switch 149E is controllable via a control line S1; and the switch 149D is connectable via a control line S2, in each case by a common control device 153 of the image sensor.

The operating mode of such a CMOS image sensor is generally known and is described in detail in DE 10 2007 045 448 A1.

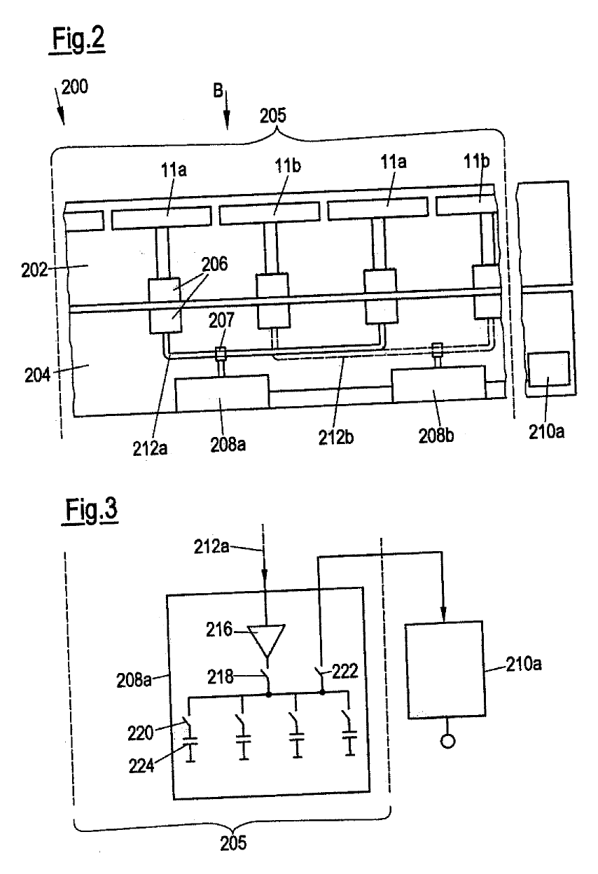

A CMOS image sensor 200 in accordance with the invention will now be described in the following with reference to FIGS. 2 to 4.

The CMOS image sensor 200 includes a first semiconductor substrate 202 and a second semiconductor substrate 204 arranged beneath the first semiconductor substrate 202 viewed in the direction of exposure B (FIG. 2). The semiconductor substrates 202, 204 are connected to one another. The first semiconductor substrate 202 can be a back-side illuminated semiconductor substrate such as has already initially been explained.

The first semiconductor substrate 202 has a plurality of pixels 11a, 11b which are arranged in rows and columns, which span an image field 205 of the CMOS image sensor and whose structure corresponds to the pixel 11 of FIG. 1 and therefore does not need to be explained again here. The pixels 11a, 11b are associated with different pixel groups, with only two pixel groups being mentioned by way of example in the following.

The pixels 11a are combined to a first pixel group and are connected via contacts 206 which are provided at the connection point between the two semiconductor substrates 202, 204 to a group line 212a, provided in the second semiconductor substrate 204 (FIG. 2). It is understood that the group line 212a can alternatively also be provided in the first semiconductor substrate 202. A respective connection switch and an associated control line are furthermore provided between the respective pixel 11a and the group line 212a to couple the respective pixel 11a selectively to the group line 212a, with the connection switches and the associated control line not being shown for better clarity.

The group line 212a is connected in accordance with FIGS. 2 and 4 via a contact 207 to an amplifier circuit 208a which is likewise provided in the second semiconductor substrate 204 and whose design will be explained in more detail in the following. The amplifier circuit 208a is arranged within the image field 205 viewed in projection along the direction of exposure B of the pixels 11a, 11b. The amplifier circuit 208a is connected to an evaluation circuit 210a arranged outside the image field 205 and forms a read-out circuit for the first pixel group with it.

A second pixel group is formed by the pixels 11b which are connected via contacts 206, connection switches (not shown) and a group line 212b shown by dashed lines to an amplifier circuit 208b (FIGS. 2 and 4). The amplifier circuit 208b is in turn connected to an evaluation circuit 210b (FIG. 4) and forms a read-out circuit with it which is associated with the second pixel group.

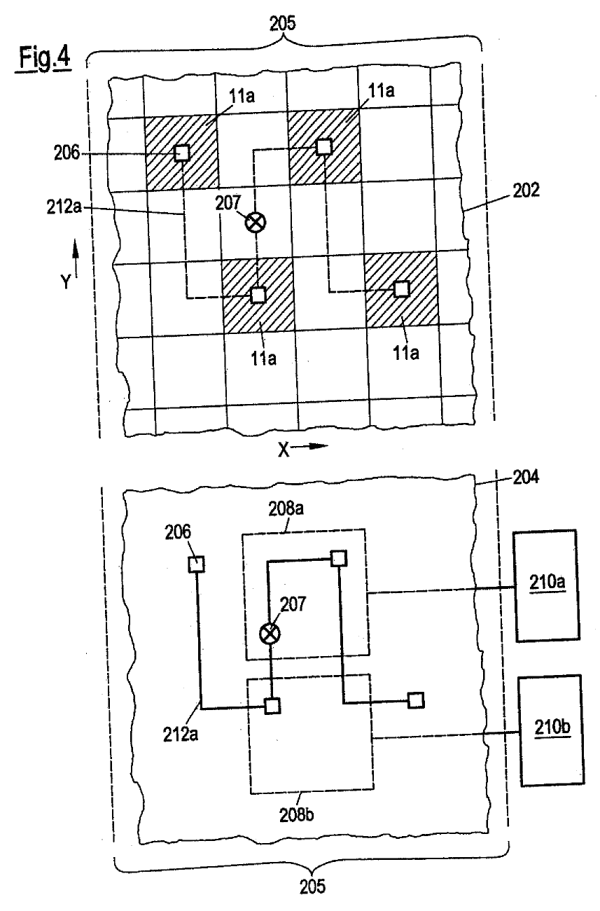

The amplifier circuit 208a includes, in accordance with FIG. 3, a plurality of memory capacitors 224, with a specific memory capacitor 224 being associated with each pixel 11a. It must be noted at this point that only the memory capacitors for the actual image signals are shown in FIG. 3 for reasons of clarity. If the initially explained correlated double sampling should be carried out by the CMOS image sensor 200 in accordance with the invention, a correspondingly increased number of memory capacitors 224 and associated switches 220 can be provided.

The amplifier circuit 208a furthermore includes an amplifier 216 which is connected at the input side to the group line 212a. A respective pixel 11a can be connected via switches 218 and 220 to the associated memory capacitor 224. The switches 220 and a switch 222 are provided for selective coupling of the memory capacitors 224 to the evaluation circuit 210a.

The respective circuit 208b is of an analog structure to the amplifier circuit 208a.

The manner will now be explained in the following with respect to FIG. 4 in which the pixels 11a belong to a pixel group and also all other pixels 11a, 11b associated with a respective pixel group are distributed over the image field 205. A detail of the first semiconductor substrate 202 is shown in a plan view in the upper image half of FIG. 4 (only image field 205). A corresponding detail of the second semiconductor substrate 204 is shown in a plan view in the lower image half (image field 205 and marginal section outside the image field 205), with the two shown details actually being arranged above one another.

In the embodiment shown here, the pattern with which the pixels 11a are distributed and are connected to the group line 212a are similar to the moves of a knight in chess. The spacing between two adjacent pixels 11a of a respective pixel group accordingly amounts to one pixel in the X direction and two pixels in the Y direction. A nesting of the pixel groups is possible without problem with such a pattern. A further pixel group can thus be displaced by one pixel in the X direction with respect to the pixel group including the pixels 11a, whereas a yet further pixel group can be displaced by one pixel in the Y direction with respect to the pixel group including the pixels 11a.

Many other patterns can, however, generally also be used. It is equally understood that the number of pixels per pixel group can also be varied. Instead of the four pixels per pixel group shown in the embodiment, pixel groups having eight or sixteen respective pixels can also be formed, for example. It is furthermore not absolutely necessary that the patterns are substantially the same for all the pixel groups of the image sensor 200, but rather completely different patterns can also be provided which, however, preferably all include the same number of pixels.

The arrangements of the pixels of a pixel group in patterns in which pixels of another pixel group are disposed between pixels of one pixel group has the advantage that no large-area artifacts can arise in the image on a failure of a read-out circuit. Any failures of read-out circuits can therefore be compensated more easily by means of interpolation. If an image sensor using a Bayer color mask is to be used, the pattern or the color mask is selected such that adjacent pixels of a pixel group have different colors.

The operation of the CMOS sensor 200 in accordance with the invention will now be explained in the following. The pixels 11a of the first pixel group are sequentially exposed during an exposure process. For this purpose, a respective pixel 11a is connected sequentially to the associated group line 212a by a corresponding control of the named connection switches and the output of the amplifier 216 is connected to the memory capacitor 224 associated with the respective pixel 11a by a corresponding control of the switch 220. The charge accumulated in the pixel 11a is converted in the pixel 11a into a voltage signal, the voltage signal is transmitted to the amplifier 216 and the voltage signal amplified there is stored in the associated memory capacitor 224. This process is repeated sequentially for all pixels 11a of the pixel group.

Subsequently (or alternating herewith), the amplified voltage signals stored in the memory capacitors 224 are sequentially transmitted to the evaluation circuit 210a by a corresponding control of the switch 222. The evaluation circuit 210a in particular includes a circuit which can in principle correspond to the column amplifier circuit 113 of FIG. 1 so that a further voltage gain takes place on the image sensor 200 (“on chip”) directly outside the image field 205 in addition to the charge-to-voltage conversion by the respective converter transistor 43 (FIG. 1) and the voltage gain by the respective amplifier 216 within the image field 205. The evaluation circuits 210a can furthermore have further devices for processing the voltage signals read out of the memory capacitors 224, for example analog-to-digital converters.

The reading out of the second and further pixel groups takes place in a corresponding manner, preferably simultaneously with the reading out of the first pixel group.

Since the amplification and buffering of the voltage signals generated by the individual pixels 11a, 11b as a rule take up a much shorter time interval than the evaluation of the buffered amplified voltage signals in the evaluation circuit 210 and 210b respectively, it is possible to reduce the time offset of the exposures of the pixels of a pixel group in comparison with an image sensor operated in the rolling shutter mode.

In the CMOS image sensor 200 in accordance with the invention, the time offset accumulated on the reading out of a complete image can be reduced so much that it lies well under the exposure time, for example less than one tenth of the exposure time. In this case, the motion blur of a moving object is namely so large that it masks the artifacts which arise by the offset of the exposure times so that distortion effects based on the exposure time offset are no longer perceivable for the observer.

Finally, the advantages of an image sensor operated in the rolling shutter mode such as simple design, high sensitivity and high dynamics can be combined with the advantages of an image sensor operated in the global shutter mode using the CMOS image sensor 200 in accordance with the invention.

Instead of the use of a first semiconductor substrate 202 and of a second semiconductor substrate 204 originally separate therefrom, the above-described structures can also be provided in different levels of a monolithic substrate.

1. An image sensor for electronic cameras,
having a plurality of light-sensitive pixels (11, 11a, 11b) which are arranged in rows and columns of an image field (205), wherein each pixel (11, 11a, 11b) comprises at least:
a light-sensitive element (15) to generate electric charge from light incident along a direction of exposure; and
a converter transistor (43) to convert a charge generated by the light-sensitive element (15) into a voltage signal at an output of the converter transistor (43),
wherein the pixels (11, 11a, 11b) form a plurality of pixel groups, with a plurality of pixels (11, 11a, 11b) being associated with each pixel group and with at least one common read-out circuit being associated with the plurality of pixels (11, 11a, 11b) of each pixel group, said read-out circuit being able to be coupled to the output of the respective converter transistor (43) of the pixels (11, 11a, 11b) of the pixel group and including an amplifier circuit (208a, 208b) for generating amplified voltage signals from the voltage signals; and
wherein the amplifier circuit (208a, 208b) of the respective pixel group is arranged within the image field (205) viewed in projection along the direction of exposure of the pixels.

2. An image sensor in accordance with claim 1,
wherein the respective amplifier circuit (208a, 208b) furthermore has at least one memory device (224) for each pixel (11, 11a, 11b) of the associated pixel group for buffering the amplified voltage signals.

3. An image sensor in accordance with claim 1,
wherein the respective read-out circuit furthermore includes at least one evaluation circuit (210a, 210b) which is adapted to evaluate the amplified voltage signals.

4. An image sensor in accordance with claim 3,
wherein the evaluation circuit (210a, 210b) is adapted to further amplify the amplified voltage signals.

5. An image sensor in accordance with claim 3,
wherein the evaluation circuit (210a, 210b) is arranged on the image sensor outside the image field (205).

6. An image sensor in accordance with claim 3,
wherein the respective amplifier circuit (208a, 208b) furthermore has at least one memory device (224) for each pixel (11, 11a, 11b) of the associated pixel group for buffering the amplified voltage signals, with the respective read-out circuit furthermore including a selection circuit (220, 222) to couple the memory devices of the associated pixel group sequentially with the associated evaluation circuit (210a, 210b) and hereby to output the buffered amplified voltage signals sequentially to the associated evaluation circuit (210a, 210b).

7. An image sensor in accordance with claim 6,
wherein the image sensor (200) has a number of read-out circuits corresponding to the number of pixel groups and having a respective amplifier circuit (208a, 208b), a respective evaluation circuit (210a, 210b) and a respective selection circuit (220, 222), with the image sensor (200) having a control device which is adapted to control at least some of the read-out circuits of different pixel groups simultaneously.

8. An image sensor in accordance with claim 1,
wherein the pixels (11, 11a, 11b) are arranged on a common first semiconductor substrate (202) and the amplifier circuits (208a, 208b) are arranged on a common second semiconductor substrate (204) connected to the first substrate (202).

9. An image sensor in accordance with claim 8,
wherein the second semiconductor substrate (204) is arranged along the direction of exposure (B) of the pixels (11, 11a, 11b) beneath the first semiconductor substrate (202).

10. An image sensor in accordance with claim 8,
wherein the first semiconductor substrate (202) is back-side illuminated.

11. An image sensor in accordance with claim 1,
wherein pixels (11b) of a different pixel group are arranged between the pixels (11a) of a respective pixel group.

12. An image sensor in accordance with claim 11,
wherein pixels (11b) of a different pixel group are arranged between the pixels (11a) of the respective pixel group both along a row direction and along a column direction.

13. An image sensor in accordance with claim 1,
wherein each pixel group has an extent of at least two pixels along a column direction and an extent of least two pixels along a row direction.

14. An image sensor in accordance with claim 1,
wherein the pixels (11, 11a, 11b) of each pixel group are arranged in a pattern which is the same or substantially the same for all pixel groups of the image sensor (200).

15. An image sensor in accordance with claim 1,
wherein each pixel furthermore includes:
a read-out node (41);
a transfer transistor (39) in order selectively to couple the light-sensitive element (15) with the read-out node (41); and
a reset transistor (45) in order selectively to couple the read-out node (41) with a reset potential (51).
